(19) United States
(12) Patent Application Publication
(10) Pub. No.: US 2026/0223495 A1
(43) Pub. Date: Jul. 30, 2026

(54) LIGHT-EMITTING DEVICE AND METHOD OF MANUFACTURING THE SAME

(71) Applicant: NICHIA CORPORATION, Anan-shi (JP)

(72) Inventor: Taichi YOSHIOKA, Tokushima-shi (JP)

(73) Assignee: NICHIA CORPORATION, Anan-shi (JP)

(21) Appl. No.: 19/457,167

(22) Filed: Jan. 23, 2026

(30) Foreign Application Priority Data
Jan. 24, 2025 (JP) 2025-010748
Aug. 4, 2025 (JP) 2025-130007

(51) Int. Cl. H10H 20/85; H10H 20/01; H10H 20/856

(52) U.S. Cl. CPC H10H 20/8506; H10H 20/0363; H10H 20/856

(57) ABSTRACT

A light-emitting device includes a light-emitting element including a semiconductor layered body having a first element surface, a second element surface opposite to the first element surface, and a plurality of element lateral surfaces between the first and second element surfaces, and a pair of electrodes; a light-transmissive member having a first surface facing the second element surface, a second surface opposite to the first surface, and a plurality of lateral surfaces between the first and second surfaces; a bonding member between the second element surface and the first surface; and a light-reflective member in contact with the element lateral surfaces of the light-emitting element, the lateral surfaces of the light-transmissive member, and a lateral surface of the bonding member, the light-reflective member being in contact with an outer peripheral region of the second element surface or an outer peripheral region of the first surface.

### CROSS-REFERENCE TO RELATED APPLICATION

This application is based on and claims priority to Japanese Patent Application No. 2025-010748, filed on January 24, 2025, and Japanese Patent Application No. 2025-130007, filed on August 4, 2025. The entire contents of these applications are incorporated herein by reference.

### TECHNICAL FIELD

The present disclosure relates to a light-emitting device and a method of manufacturing the light-emitting device.

### BACKGROUND

A light-emitting device in which a light-transmissive member is bonded to an emission surface of a light-emitting element with a light-transmissive bonding member interposed therebetween and lateral surfaces of these members are covered with a covering member has been proposed (for example, Japanese Unexamined Patent Application Publication No. 2017-050359).

### SUMMARY

Embodiments of the present disclosure provide a light-emitting device that enables improvement of the uniformity of the luminance distribution on a light extraction surface, and a method of manufacturing the light-emitting device.

A light-emitting device according to one embodiment of the present disclosure includes a light-emitting element, a light-transmissive member, a bonding member, and a light-reflective member. The light-emitting element includes a semiconductor layered body and a pair of electrodes. The semiconductor layered body has a first element surface, a second element surface opposite to the first element surface, and a plurality of element lateral surfaces between the first element surface and the second element surface. The light-transmissive member has a first surface facing the second element surface, a second surface opposite to the first surface, and a plurality of lateral surfaces between the first surface and the second surface. The bonding member is disposed between the second element surface of the light-emitting element and the first surface of the light-transmissive member. The light-reflective member is in contact with the element lateral surfaces of the light-emitting element, the lateral surfaces of the light-transmissive member, and a lateral surface of the bonding member. The light-reflective member is further in contact with an outer peripheral region of the second element surface of the light-emitting element or an outer peripheral region of the first surface of the light-transmissive member.

A method of manufacturing a light-emitting device according to another embodiment of the present disclosure includes: providing a light-emitting element including a semiconductor layered body having a first element surface, a second element surface opposite to the first element surface, and a plurality of element lateral surfaces between the first element surface and the second element surface, and a pair of electrodes; providing a light-transmissive member having a first surface facing the second element surface, a second surface opposite to the first surface, and a plurality of lateral surfaces between the first surface and the second surface; disposing an unhardened bonding member on the second element surface or on the first surface; hardening the bonding member in a state in which the unhardened bonding member is caused to extend on at least a portion of the element lateral surfaces of the light-emitting element and at least a portion of the lateral surfaces of the light-transmissive member by pressing the unhardened bonding member disposed between the second element surface and the first surface via the light-transmissive member or the light-emitting element; at least partially removing the bonding member covering at least a portion of the element lateral surfaces of the light-emitting element and at least a portion of the lateral surfaces of the light-transmissive member to at least partially expose an outer peripheral region of the second element surface of the light-emitting element or an outer peripheral region of the first surface of the light-transmissive member; and forming a light-reflective member in contact with the element lateral surfaces of the light-emitting element, the lateral surfaces of the light-transmissive member, a lateral surface of the bonding member, and the outer peripheral region of the second element surface of the light-emitting element or the outer peripheral region of the first surface of the light-transmissive member.

According to a light-emitting device of embodiments of the present disclosure, it is possible to avoid projection of a bonding member from lateral surfaces of a light-emitting element or a light-transmissive member and to improve uniformity of the luminance distribution on a light extraction surface.

### BRIEF DESCRIPTION OF THE DRAWINGS

FIG. 1A is a schematic top view of an example of a light-emitting device according to an embodiment.

FIG. 1B is a schematic cross-sectional view taken along the line IB-IB of FIG. 1A and a schematic partial enlarged view of the cross-sectional view.

FIG. 2 is a schematic cross-sectional view of another example of the light-emitting device according to the embodiment.

FIG. 3 is a schematic cross-sectional view of still another example of the light-emitting device according to the embodiment.

FIG. 4 is a schematic cross-sectional view of still another example of the light-emitting device according to the embodiment.

FIG. 5 is a schematic cross-sectional view of still another example of the light-emitting device according to the embodiment.

FIG. 6A is a schematic cross-sectional view illustrating a method of manufacturing a light-emitting device according to the embodiment.

FIG. 6B is a schematic cross-sectional view illustrating the method of manufacturing a light-emitting device according to the embodiment.

FIG. 6C is a schematic cross-sectional view illustrating the method of manufacturing a light-emitting device according to the embodiment.

FIG. 6D is a schematic cross-sectional view illustrating the method of manufacturing a light-emitting device according to the embodiment and a schematic partial enlarged view of the cross-sectional view.

FIG. 6E is a schematic cross-sectional view illustrating the method of manufacturing a light-emitting device according to the embodiment and a schematic partial enlarged view of the cross-sectional view.

FIG. 6F is a schematic cross-sectional view illustrating the method of manufacturing a light-emitting device according to the embodiment and a schematic partial enlarged view of the cross-sectional view.

FIG. 6G is a schematic cross-sectional view illustrating the method of manufacturing a light-emitting device according to the embodiment and a schematic partial enlarged view of the cross-sectional view.

FIG. 6H is a schematic cross-sectional view illustrating the method of manufacturing a light-emitting device according to the embodiment.

FIG. 7 is a schematic cross-sectional view illustrating an example of a modification of the light-emitting device according to the embodiment and a schematic partial enlarged view of the cross-sectional view.

### DETAILED DESCRIPTION

Certain embodiments of the present invention will be described below in detail on the basis of the accompanying drawings. In the description below, terms indicating specific directions or positions (such as “up,” “down,” “right,” “left,” and other terms related to these terms) will be used when appropriate. These terms are used to facilitate understanding of the present invention referring to the drawings, and the meanings of these terms do not limit the technical scope of the present invention. As for a resin material or the like, the same name will be used for description regardless of before or after molding, hardening, curing, or singulation. That is, a member that changes state according to the phase in a process, such as the case in which the member is liquid before molding, becomes solid after molding, and further becomes individual small pieces by cutting the solid after molding to change the shape, will be described using the same name.

A light-emitting device according to the embodiment includes a light-emitting element, a light-transmissive member, a bonding member, and a light-reflective member.

The light-emitting element includes a semiconductor layered body and a pair of electrodes. The semiconductor layered body has a first element surface, a second element surface opposite to the first element surface, and a plurality of element lateral surfaces between the first element surface and the second element surface. The pair of electrodes are disposed on the first element surface of the semiconductor layered body.

The light-transmissive member has a first surface, a second surface opposite to the first surface, and a lateral surface(s) between the first surface and the second surface. The first surface is a surface facing the second element surface of the light-emitting element.

The bonding member is disposed between the second element surface of the light-emitting element and the first surface of the light-transmissive member. The bonding member is in contact with an inner region of the second element surface of the light-emitting element such that an outer peripheral region of the second element surface is exposed and is in contact with the entire first surface of the light-transmissive member. Alternatively, the bonding member is in contact with an inner region of the first surface of the light-transmissive member such that an outer peripheral region of the light-transmissive member is exposed and is in contact with the entire second element surface of the light-emitting element.

The light-reflective member is in contact with the element lateral surface of the light-emitting element, the lateral surface of the light-transmissive member, and a lateral surface of the bonding member. Further, the light-reflective member is in contact with the outer peripheral region of the second element surface of the light-emitting element or the outer peripheral region of the first surface of the light-transmissive member in a top view.

A light-emitting device 100 can further include an electroconductive member configured to conduct electricity to the light-emitting element.

### FIRST EMBODIMENT

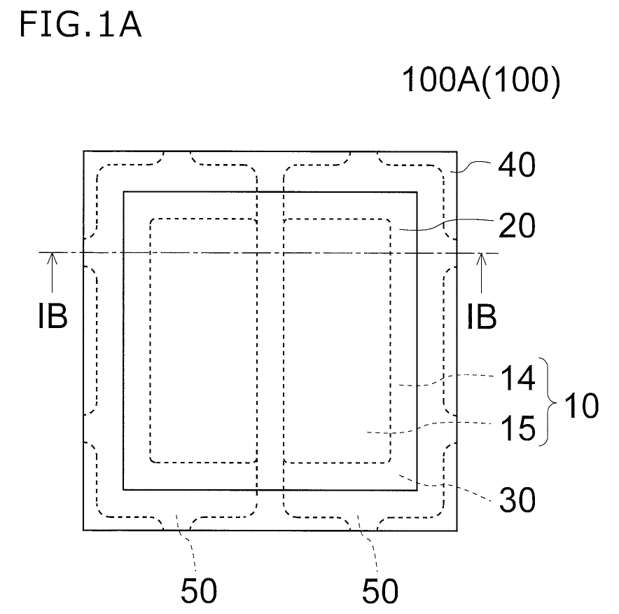

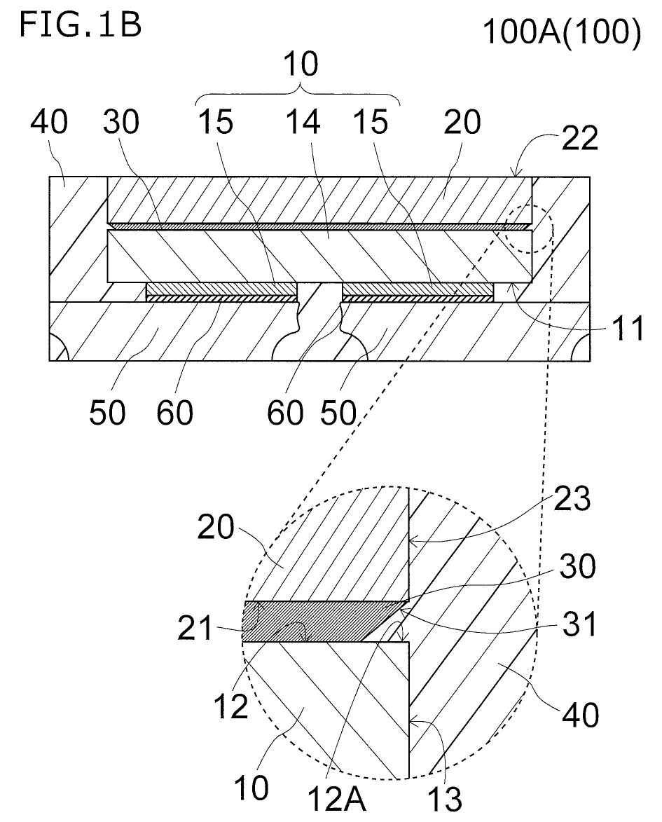

FIGS. 1A and 1B show the light-emitting device 100 according to the embodiment. A light-emitting device 100A includes a light-emitting element 10, a light-transmissive member 20, a bonding member 30, and a light-reflective member 40.

The light-emitting element 10 includes a semiconductor layered body 14 and a pair of electrodes 15. The semiconductor layered body 14 has a first element surface 11, a second element surface 12 opposite to the first element surface 11, and a plurality of element lateral surfaces 13 between the first element surface 11 and the second element surface 12. As shown in FIG. 1B, the light-emitting element 10 can have a structure in which the pair of electrodes 15 are disposed on the first element surface 11.

The light-transmissive member 20 is disposed on the second element surface 12 of the light-emitting element 10 with the bonding member 30 disposed therebetween. The light-transmissive member 20 has a first surface 21 facing the second element surface 12 of the light-emitting element 10, a second surface 22 opposite to the first surface 21, and a plurality of lateral surfaces 23 between the first surface 21 and the second surface 22.

The light-emitting element 10 and the light-transmissive member 20 have substantially the same size and shape in a top view. The term “substantially the same” refers to the state that the area of the light-emitting element 10 in a top view is within the range of 95% to 105% of the area of the light-transmissive member 20. In other words, substantially the same size and shape refer to the state that the outer periphery of the light-emitting element 10 and the outer periphery of the light-transmissive member 20 substantially coincide with each other in a top view.

The bonding member 30 is in contact with the second element surface 12 of the light-emitting element 10 and the first surface 21 of the light-transmissive member 20. Specifically, the bonding member 30 is in contact with the light-emitting element 10 only in an inner region surrounded by an outer peripheral region 12A of the second element surface 12 of the light-emitting element 10 and is not in contact with the outer peripheral region 12A. In other words, the outer peripheral region 12A of the second element surface 12 of the light-emitting element 10 is exposed from the bonding member 30. The bonding member 30 is in contact with the entire first surface 21 of the light-transmissive member 20. That is, in a cross-sectional view, an upper end of a lateral surface 31 of the bonding member 30 is located outward of a lower end of the lateral surface 31 of the bonding member 30.

The element lateral surfaces 13 of the light-emitting element 10, the lateral surfaces 23 of the light-transmissive member 20, and the lateral surface 31 of the bonding member 30 are in contact with and covered with the light-reflective member 40. In the example shown in FIG. 1B, the light-reflective member 40 is further in contact with the outer peripheral region 12A of the second element surface 12 of the light-emitting element 10. That is, in the outer peripheral region 12A of the second element surface 12 of the light-emitting element 10, the light-reflective member 40 is located between the second element surface 12 and the bonding member 30. Accordingly, light emitted from the light-emitting element 10 is not emitted from the entire second element surface 12 but from the inner region surrounded by the outer peripheral region 12A of the second element surface 12. The extraction of light from an outer peripheral portion of the second surface 22 of the light-transmissive member 20 in a top view can therefore be improved. Accordingly, it becomes possible to suppress the outer peripheral portion from being dark and to improve the luminance distribution.

Further, as shown in FIG. 1B, the extraction of light from the outer peripheral portion can be more efficiently improved in a case in which the lateral surface 31 of the bonding member 30 is formed as an inclined surface. The term “inclined surface” as used herein refers to not only the case in which, in a cross-sectional view as shown in FIG. 1B, a straight line connecting the upper end and the lower end of the lateral surface 31 of the bonding member 30 forms one inclined surface, but also to a surface in which the upper end is located outward of the lower end, such as a curved surface, an uneven surface, and an irregular surface. By allowing the lateral surface 31 of the bonding member 30 to be inward of the element lateral surface 13 of the light-emitting element 10 and the lateral surface 23 of the light-transmissive member 20, the light-reflective member 40 can partially have protrusion between the second element surface 12 of the light-emitting element 10 and the first light-transmissive surface 21 of the light-transmissive member 20.

The light-emitting devices 100 shown in FIGS. 1A to 5 share the above constitution and differ from one another in the structure including other members. The light-emitting device 100A shown in FIGS. 1A and 1B includes a pair of electroconductive members 50. For example, the electroconductive members 50 can be formed from a plate-shaped lead frame. The light-reflective member 40 is in contact with upper surfaces of the pair of electroconductive members 50. The light-reflective member 40 is further disposed between the pair of electroconductive members 50. The electroconductive member 50 and the electrode 15 of the light-emitting element 10 are bonded with electroconductive bonding member 60.

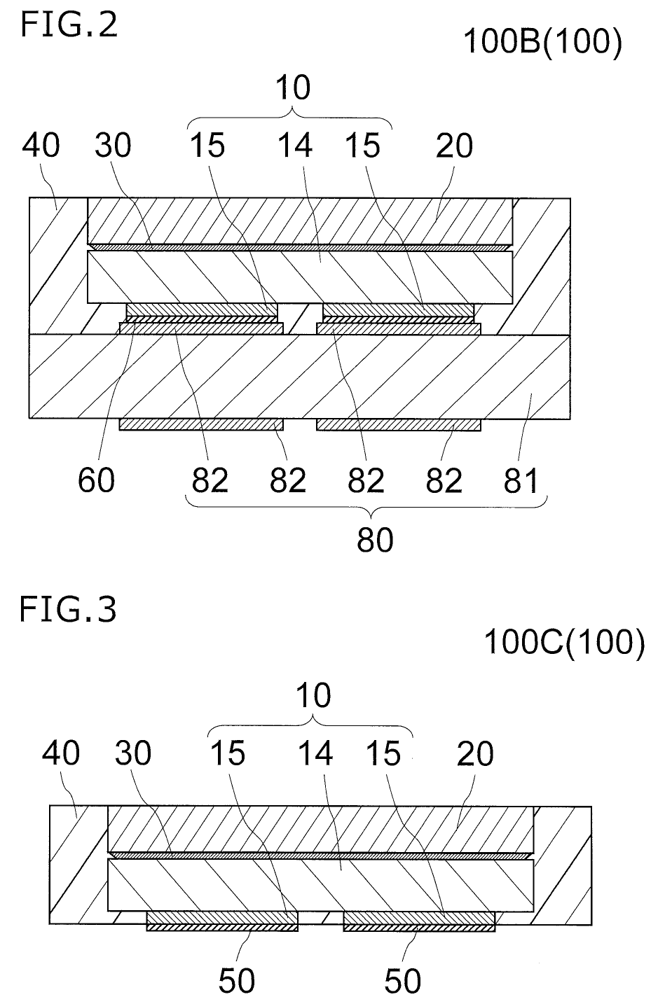

A light-emitting device 100B shown in FIG. 2 includes a substrate 80 including an insulating substrate 81 and electroconductive members 82 disposed on an upper surface and a lower surface of the substrate 81. The light-emitting element 10 is bonded to the electroconductive members 82 of the substrate 80 with the electroconductive bonding members 60 interposed therebetween.

A light-emitting device 100C shown in FIG. 3 includes electroconductive members 50 that are thin film layers covering the lower surfaces of the electrodes 15 of the light-emitting element 10. In the example shown in FIG. 3, the electroconductive members 50 cover only the lower surfaces of the electrodes 15 of the light-emitting element 10 but are not limited to this structure. The electroconductive members 50 can continuously cover the lower surfaces of the electrodes 15 of the light-emitting element 10 and the lower surface of the light-reflective member 40.

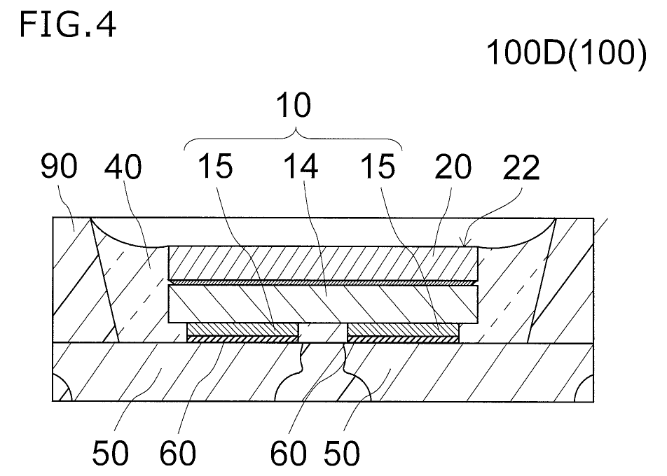

A light-emitting device 100D shown in FIG. 4 includes a package having a recessed portion in which an electronic component such as the light-emitting element 10 can be disposed. The package includes a pair of electroconductive members 50 and an insulating base 90. Examples of the base 90 include a resin package, a ceramic package, and a glass epoxy package. The light-reflective member 40 is disposed in the recessed portion such that the second surface 22 of the light-transmissive member 20 is exposed. The same or a similar material as for the light-reflective member 40 shown in FIG. 1B and other drawings can be used for the base 90. Alternatively, the same or a similar material as for the substrate 81 of the substrate 80 shown in FIG. 2 can be used.

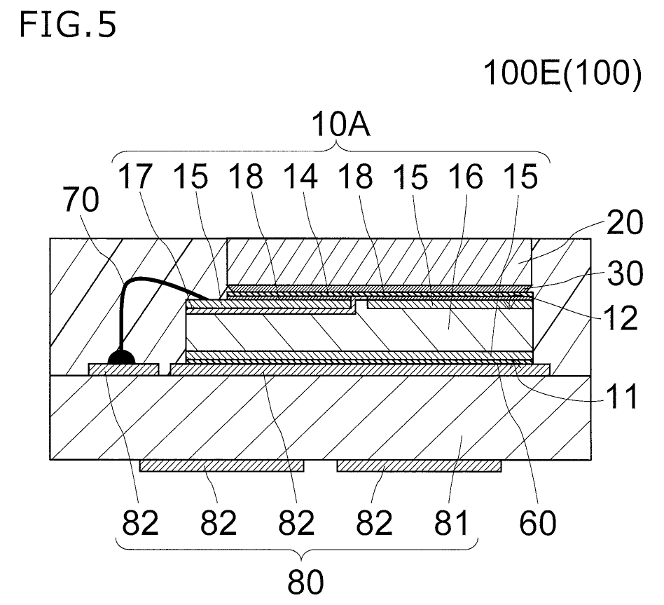

A light-emitting device 100E shown in FIG. 5 differs from the other examples in the structure of a light-emitting element 10A. Further, one of electrodes 15 of the light-emitting element 10A is electrically bonded to electroconductive member 82 of the substrate 80 via a wire 70 formed of gold, silver, or the like as a main component. The light-emitting element 10A includes an electroconductive element substrate 16 and the electrodes 15 disposed on the upper and lower surfaces of the element substrate 16. The electrode 15 disposed on the lower surface of the element substrate 16 is electrically connected to the electroconductive member 82 of the substrate 80 with the electroconductive bonding member 60 interposed therebetween. One of the electrodes 15 disposed on the upper surface of the element substrate 16 (right electrode 15 in FIG. 5) is in contact with the element substrate 16 and is electrically connected to the semiconductor layered body 14 with a metal layer 18 interposed therebetween. The other electrodes 15 disposed on the upper surface of the element substrate 16 (left electrode 15 in FIG. 5) is disposed on the element substrate 16 with an insulating layer 17 formed of silicon oxide, aluminum oxide, or the like interposed therebetween and is electrically connected to the semiconductor layered body 14 with the metal layer 18 formed of titanium, gold, platinum, or the like interposed therebetween. Further, the other electrode 15 (left electrode 15 in FIG. 5) extends in the lateral direction beyond the semiconductor layered body 14 on the element substrate 16, and the wire 70 is bonded to the extending portion. The other end of the wire 70 is bonded to the electroconductive member 82 of the substrate 80.

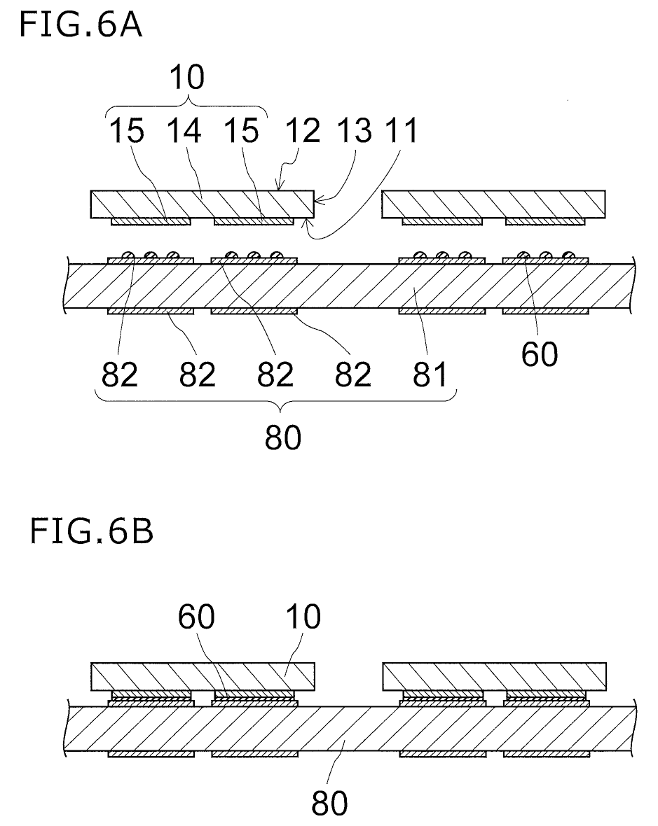

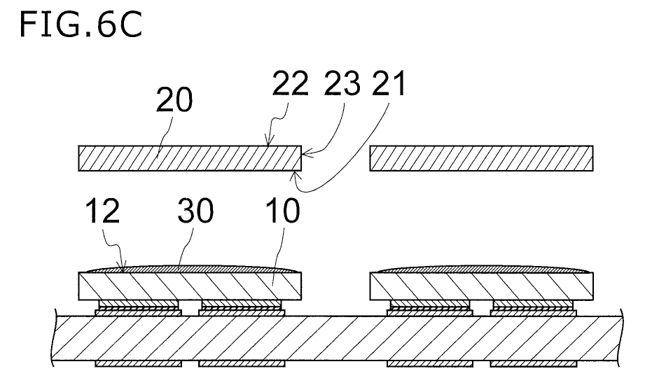

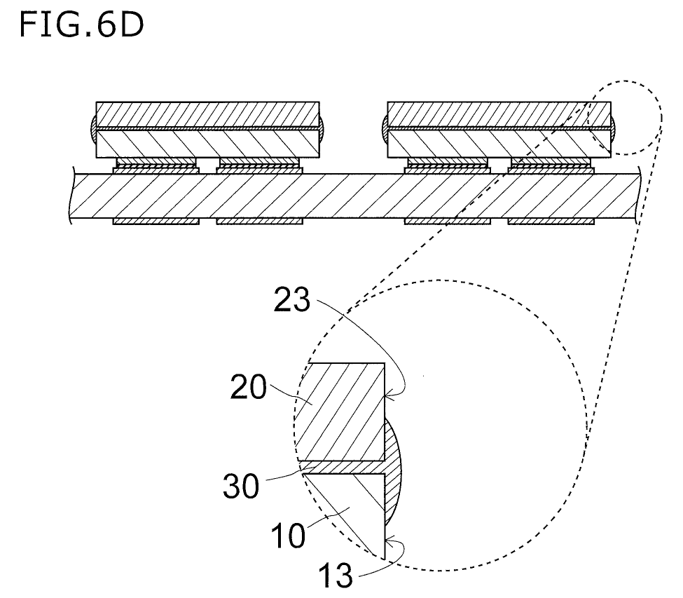

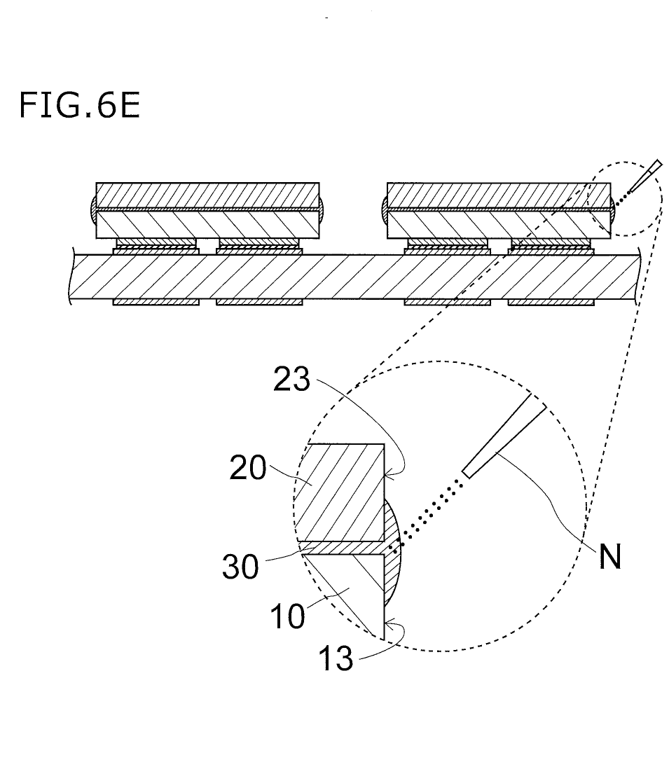

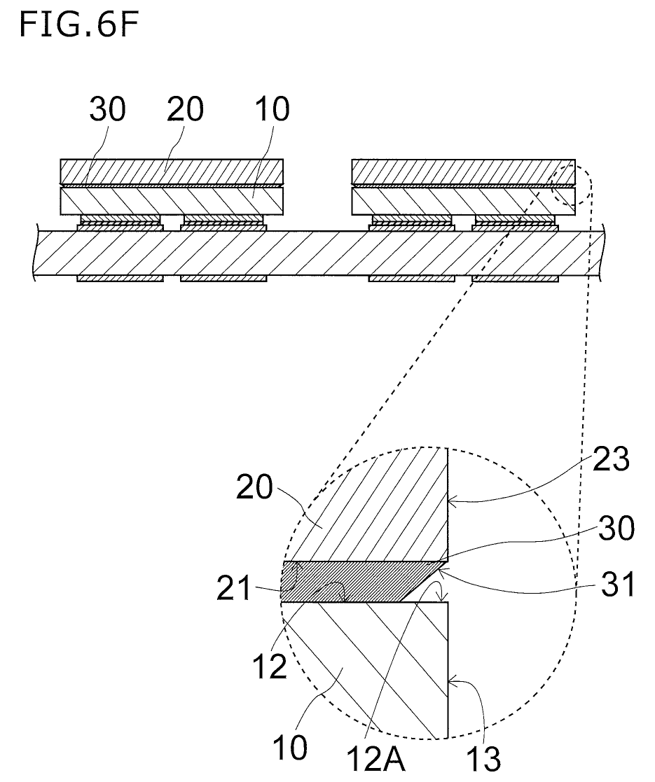

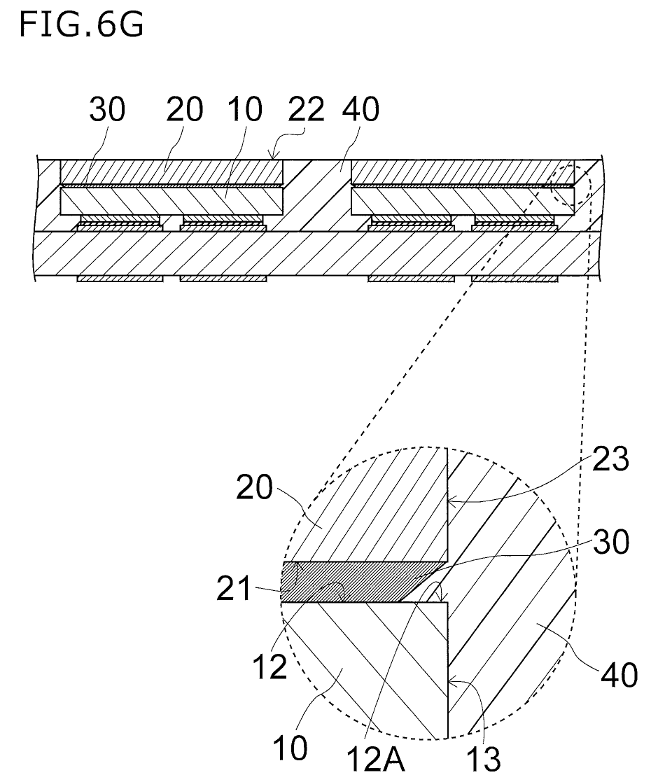

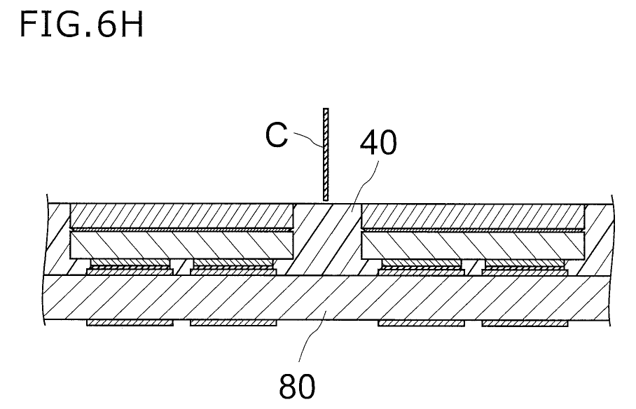

FIGS. 6A to 6H show an example of the manufacturing process of the light-emitting device 100B (100) shown in FIG. 2. A method of manufacturing the light-emitting device 100B mainly includes the following steps:

(1) providing a light-emitting element,

(2) providing a light-transmissive member,

(3) disposing a bonding member,

(4) hardening the bonding member,

(5) removing the bonding member, and

(6) forming a light-reflective member.

Each step will be described in detail.

### 1. Providing Light-Emitting Element

The light-emitting element 10 is provided. The light-emitting element 10 includes the semiconductor layered body 14 and the electrodes 15. The semiconductor layered body 14 has the first element surface 11 on which the electrodes 15 are disposed, the second element surface 12 opposite to the first element surface 11, and the element lateral surfaces 13 between the first element surface 11 and the second element surface 12. The substrate 80 is also provided. The substrate 80 includes the insulating substrate 81 and the electroconductive members 82. Subsequently, the electroconductive bonding members 60 are disposed on the electroconductive members 80 of the substrate 80 or on the surfaces of the electrodes 15 opposite to the surfaces in contact with the semiconductor layered body 14. In the example shown in FIG. 6A, the electroconductive bonding members 60 are disposed on the electroconductive member 82 of the substrate 80. The light-emitting element 10 and the substrate 80 can be provided by purchasing or the like or by purchasing raw materials and performing a predetermined manufacturing process. The electroconductive bonding members 60 can be formed by a method such as transfer, printing, and potting. In the example shown in FIG. 6A, a plurality of electroconductive bonding members 60 are disposed on one electroconductive member 82 but are not limited to this structure. One electroconductive bonding member 60 can be disposed on one electroconductive member 82. As shown in FIG. 6A, in the case in which a plurality of small electroconductive bonding members 60 are disposed as the electroconductive bonding members 60, flux can be applied on the electroconductive bonding members 60 as a tacking material. Also in the case in which one electroconductive bonding member 60 is disposed on one electroconductive member 82, flux can be applied on the electroconductive bonding member 60 to improve fusibility of the electroconductive bonding member 60.

Subsequently, the electroconductive members 82 on the substrate 80 are arranged to face the first element surface 11 of the light-emitting element 10, and the substrate 80 and the light-emitting element 10 are bonded together as shown in FIG. 6B. In the case in which solder, metal paste, or the like is used as the electroconductive bonding members 60, bonding can be achieved by heating to melt the electroconductive bonding members 60 and then cooling. In the case in which bumps are used, bonding can be achieved by applying ultrasonic waves and pressure.

### 2. Providing Light-Transmissive Member

The light-transmissive member 20 is provided. The light-transmissive member 20 has the first surface 21, the second surface 22 opposite to the first surface 21, and the lateral surfaces 23 between the first surface 21 and the second surface 22. The light-transmissive member 20 can be provided by purchasing or the like or by purchasing raw materials and performing a predetermined manufacturing process.

### 3. Disposing Bonding Member

As shown in FIG. 6C, the unhardened bonding member 30 is disposed on the second element surface 12 of the light-emitting element 10. The unhardened bonding member 30 can be disposed by a method such as potting, printing, spraying, and transfer. As shown in FIG. 6C, the first surface 21 of the light-transmissive member 20 is then arranged to face the bonding member 30 on the second element surface 12 of the light-emitting element 10, and the light-transmissive member 20 is disposed on the bonding member 30. Before the unhardened bonding member 30 is hardened, the light-transmissive member 20 is pressed. As shown in FIG. 6D, the bonding member 30 thereby extends on the element lateral surfaces 13 of the light-emitting element 10 and the lateral surfaces 23 of the light-transmissive member 20.

The term “unhardened” as used herein refers to not only a material that is not hardened at all but also includes a material hardened to an extent that the material can be deformed by pressing or the like. For example, the term includes a state in which the hardening reaction has progressed relative to the initial state during storage in a supply container, or during a waiting period after the material is disposed on the light-emitting element 10 and before the light-transmissive member 20 is disposed thereon in the manufacturing process.

### 4. Hardening Bonding Member

Heating is performed in a state in which the bonding member 30 covers the element lateral surfaces 13 of the light-emitting element 10 and the lateral surfaces 23 of the light-transmissive member 20 as described above, so that the bonding member 30 is hardened. After the bonding member 30 is hardened, the second element surface 12 of the light-emitting element 10 and the first surface 21 of the light-transmissive member 20 are each entirely in contact with the bonding member 30 as shown in FIG. 6D.

### 5. Removing Bonding Member

Subsequently, a portion of the hardened bonding member 30 is removed. Examples of the removal methods include a removal method of discharging dry ice particles and causing the dry ice particles to collide with the bonding member 30 and a removal method of discharging a particulate abrasive material and causing the particulate abrasive material to collide with the bonding member 30. As the dry ice particles, for example, particles having a size of 10 μm or more and 200 μm or less can be used. Examples of the abrasive material used include silica sand, aluminum oxide, glass beads, iron, and nylon beads. For example, the size of these abrasives material can be 10 μm or more and 200 μm or less. The at least partial removing of the bonding member 30 can include discharging the dry ice particle with an exit of a nozzle N configured to discharge the dry ice particle being inclined with respect to the element lateral surfaces 13 of the light-emitting element 10 or the lateral surfaces 23 of the light-transmissive member 20 such that the nozzle scans in a thickness direction of the bonding member 30. Further, the at least partial removing of the bonding member 30 can include forming at least a portion of the lateral surface 31 of the bonding member 30 into a shape depressed from the element lateral surfaces 13 of the light-emitting element 10 or the lateral surfaces 23 of the light-transmissive member 20 in a cross-sectional view. Still further, the at least partial removing of the bonding member 30 includes forming the lateral 31 surface of the bonding member 30 into an inclined surface in a cross-sectional view.

For example, in the example shown in FIG. 6E, dry ice particles are discharged obliquely from above onto the bonding member 30 covering the lateral surfaces 23 of the light-transmissive member 20 and the element lateral surfaces 13 of the light-emitting element 10 in a state in which a nozzle N that can discharge dry ice particles is disposed such that the discharge direction extends obliquely downward. As shown in FIG. 6F, the bonding member 30 covering the lateral surfaces 23 of the light-transmissive member 20 and the element lateral surfaces 13 of the light-emitting element 10 is thereby removed. Further, by discharging the dry ice particles obliquely from above, the bonding member 30 covering the outer peripheral region 12A of the second element surface 12 of the light-emitting element 10 is also removed. The range in which the bonding member 30 covering the second element surface 12 is removed, that is, the range of the element outer peripheral region 12A of the second element surface 12, can be, for example, 1% to 10% of the area of the second element surface 12. Alternatively, from another viewpoint, the range can be 5 μm to 50 μm from the outer edge of the second element surface 12. The range of the outer peripheral region 12A of the second element surface 12 can be adjusted using the discharge speed of the dry ice particles, the discharge intensity, the discharge direction, and the like. For example, the angle of the nozzle N can be within the range of 10 degrees to 80 degrees relative to the second element surface 12 of the light-emitting element 10.

### 6. Forming Light-Reflective Member

Subsequently, as shown in FIG. 6G, the light-reflective member 40 is formed. The light-reflective member 40 is disposed such that the second surface 22 of the light-transmissive member 20 is exposed. At this time, the light-reflective member 40 is in contact with the outer peripheral region 12A of the second element surface 12 of the light-emitting element 10 in addition to the element lateral surfaces 13 of the light-emitting element 10 and the lateral surfaces 23 of the light-transmissive member 20. The light-reflective member 40 can be formed in one step as shown in FIG. 6G or in two or more steps. For example, the light-reflective member 40 can include: a first light-reflective member in contact with the light-emitting element 10 and the light-transmissive member 20; and a second light-reflective member covering the first light-reflective member.

Examples of the methods of forming the light-reflective member 40 include compression molding, transfer molding, potting, printing, and spraying. Subsequently, the substrate 80 and the light-reflective member 40 are cut using a cutting blade C, such as a dicing saw as shown in FIG. 6H, to provide the light-emitting device 100B as shown in FIG. 2.

### MODIFIED EXAMPLES

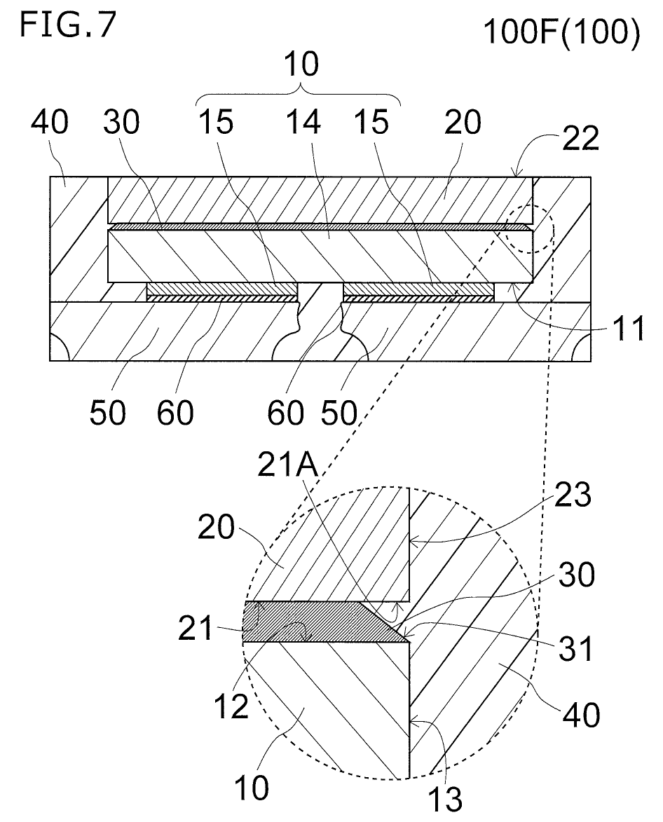

In a light-emitting device 100F shown in FIG. 7, the outer peripheral region 21A of the first surface 21 of the light-transmissive member 20 is exposed from the bonding member 30, and the exposed light-transmissive outer peripheral region 21A is in contact with the light-reflective member 40. Further, the entire second element surface 12 of the light-emitting element 10 is in contact with the bonding member 30. Except as described above, the configuration is substantially the same as that of the light-emitting device 100A shown in FIG. 1B. By directing the lateral surface 31 of the bonding member 30 obliquely upward as described above, the central luminance distribution on the light extraction surface can be enhanced. The bonding member 30 having such a shape can be obtained by causing the second element surface 12 of the light-emitting element 10 to be located above the first surface 21 of the light-transmissive member 20, that is, the light-transmissive member 20 and the light-emitting element 10 are disposed upside down compared with the arrangement in FIG. 6E, and discharging the dry ice particles obliquely from above.

Each member will be described below in detail.

### Light-Emitting Element

The light-emitting device includes one or two or more light-emitting elements. For example, a semiconductor light-emitting element such as a light-emitting diode can be used as the light-emitting element. The light-emitting element includes a semiconductor layered body and a pair of positive and negative electrodes. The semiconductor layered body has a first element surface, a second element surface opposite to the first element surface, and a plurality of element lateral surfaces between the first element surface and the second element surface. For example, an element substrate formed of sapphire, silicon, or the like and a semiconductor layer formed on the element substrate are included. Alternatively, the semiconductor layered body can consist of the semiconductor layer without the element substrate. The element substrate can be a growth substrate for growing the semiconductor layer or can be a bonded substrate formed by bonding the semiconductor layer after the growth. The light-emitting element can include an insulating layer, a metal layer, and the like. The shape of the light-emitting element in a top view can be a polygonal shape such as a triangular shape, a quadrangular shape, and a hexagonal shape. For example, the size of the light-emitting element can be such that a side measures 100 μm or more and 3,000 μm or less in a top view. In the case in which a plurality of light-emitting elements are included, the sizes, the emission wavelengths, the compositions, and the like of the light-emitting elements can be the same, or some or all of them can be different. A plurality of light-emitting elements can be all connected in series or in parallel or can be connected such that series and parallel connections are mixed.

The semiconductor layered body includes an n-type semiconductor layer, a p-type semiconductor layer, and a light-emitting layer interposed between these layers. The semiconductor layered body including such a light-emitting layer can contain, for example, InxAlyGa1−x−yN (0 ≤ x, 0 ≤ y, and x + y ≤ 1).

The semiconductor layered body can have a structure including one or more light-emitting layers between the n-type semiconductor layer and the p-type semiconductor layer or can have a structure in which a structure including the n-type semiconductor layer, the light-emitting layer, and the p-type semiconductor layer in order is repeated. In the case in which the semiconductor layered body includes a plurality of light-emitting layers, the semiconductor layered body can include light-emitting layers with different peak emission wavelengths or light-emitting layers with the same peak emission wavelength. The expression “the same peak emission wavelength” includes the case in which there are variations of approximately several nanometers. The combination of peak emission wavelengths of a plurality of light-emitting layers can be appropriately selected. For example, in the case in which the semiconductor layered body includes two light-emitting layers, the combination of light-emitting layers can be selected from blue light and blue light, green light and green light, red light and red light, ultraviolet light and ultraviolet light, blue light and green light, blue light and red light, and green light and red light.

The light-emitting element includes at least a pair of electrodes on the first element surface of the semiconductor layered body. In other words, one light-emitting element includes at least one positive electrode and at least one negative electrode as the electrodes.

For the electrodes of the light-emitting element, a good electric conductor can be used, and the electrodes can be formed of, for example, gold, silver, copper, platinum, iron, nickel, or an alloy of these metals. The electrodes can include an ohmic electrode in contact with the first element surface of the semiconductor layered body and a pad electrode connected to the ohmic electrode and connected to an external device. The thickness of the electrode can be, for example, 0.5 μm or more and 100 μm or less, more preferably 5 μm or more and 50 μm or less.

### Light-Transmissive Member

The light-transmissive member is a member that is light-transmissive and defines the light extraction surface of the light-emitting device. Light emitted from the light-emitting element is emitted to the outside through the light-transmissive member. The light-transmissive member has a first surface, a second surface opposite to the first surface, and a plurality of lateral surfaces between the first surface and the second surface. The first surface is arranged to face the second element surface of the light-emitting element.

For the light-transmissive member, a resin member, an inorganic member, glass, or a combination of these can be used. The light-transmissive member preferably has a transmittance of 60% or more at a peak wavelength of light emitted from the light-emitting element, more preferably 70% or more, and still more preferably 80% or more.

For the resin member as the light-transmissive member, a thermosetting resin such as a silicone resin, a modified silicone resin, an epoxy resin, and a phenolic resin, or a thermoplastic resin such as a polycarbonate resin, an acrylic resin, a methylpentene resin, and a polynorbornene resin can be used. A silicone resin, which has good resistance to light and heat, is particularly suitable. For the inorganic member as the light-transmissive member, silicon oxide, aluminum oxide, or the like can be used. As the glass, alkali-free glass, soda glass, soda-lime glass, borosilicate glass, aluminosilicate glass, silica glass, low-alkali borosilicate glass, or the like can be used.

The light-transmissive member can consist of the member that is light-transmissive described above or can be a member in which the member that is light-transmissive described above is a base material, and a wavelength conversion substance that is excited by light emitted from the light-emitting element to convert the light into light with a different wavelength, such as a phosphor, and/or a light-scattering agent, or the like is contained. A multilayer structure can be employed in which the plate-shaped member that is light-transmissive described above is a base material, and a wavelength conversion substance such as a phosphor, and/or a light-scattering agent, or the like is disposed on a surface of the base material.

Examples of the phosphor include yttrium-aluminum-garnet based phosphors, lutetium-aluminum-garnet based phosphors, terbium-aluminum-garnet based phosphors, CCA based phosphors, SAE based phosphors, chlorosilicate based phosphors, silicate based phosphors, oxynitride based phosphors such as β-SiAlON based phosphors and α-SiAlON based phosphors, nitride based phosphors such as LSN based phosphors, BSESN based phosphors, SLA based phosphors, CASN based phosphors, and SCASN based phosphors, fluoride based phosphors such as KSF based phosphors, KSAF based phosphors, and MGF based phosphors, quantum dots having the perovskite structure, group II–VI quantum dots, group III–V quantum dots, and quantum dots having the chalcopyrite structure.

Examples of the light-scattering agent include particles of titanium oxide, silicon oxide, aluminum oxide, zinc oxide, magnesium oxide, zirconium oxide, yttrium oxide, calcium fluoride, magnesium fluoride, niobium pentoxide, barium titanate, tantalum pentoxide, barium sulfate, glass, or the like.

### Bonding Member

The bonding member is a member that is light-transmissive disposed between the light-emitting element and the light-transmissive member. Specifically, the bonding member is in contact with an inner region of the second element surface of the light-emitting element such that an outer peripheral region of the second element surface is exposed and is in contact with the entire first surface of the light-transmissive member. Alternatively, the bonding member is in contact with an inner region of the first surface of the light-transmissive member such that an outer peripheral region of the first surface is exposed and is in contact with the entire second element surface of the light-emitting element. A lateral surface of the bonding member is preferably an inclined surface.

As a material of the bonding member, a thermosetting resin such as a silicone resin, a modified silicone resin, an epoxy resin, and a phenolic resin or a thermoplastic resin such as a polycarbonate resin, an acrylic resin, a methylpentene resin, and a polynorbornene resin can be used. A silicone resin, which has good resistance to light and heat, is particularly suitable. Alternatively, as a material of the bonding member, an inorganic member such as a polysilazane cured product obtained by curing a polysilazane, silicon oxide, and aluminum oxide can be used. The polysilazane is formed of an organic polysilazane having organic groups, an inorganic polysilazane having no organic group, or a mixture of these polysilazanes and is a polymer compound having a repeating unit represented by (-Si-N-) in the molecule. A polysilazane is suitable as a material of the bonding member of the light-emitting device in that a material having a lower refractive index than the refractive index of the light-transmissive member can be readily selected, spreading over the light-transmissive member when softened is good and thus a thin film is easily formed, and the like. The polysilazane cured product has different compositions after curing according to the type of the raw material polysilazane, curing conditions, or the like. That is, the polysilazane cured product includes the structure represented by (-Si-N-) in some cases and does not contain the structure in other cases. In the case in which the polysilazane cured product derived from an inorganic polysilazane does not contain the structure represented by (-Si-N-), the cured product is silicon oxide. The polysilazane cured product derived from an organic polysilazane contains organic groups. In the case in which the light-emitting element can emit ultraviolet rays, by using a bonding member containing a polysilazane cured product mainly consisting of an inorganic material, a light-emitting device having better heat resistance and the like can be provided than in the case of a bonding member mainly formed of a resin. As a material of the bonding member, glass such as alkali-free glass, soda glass, soda-lime glass, borosilicate glass, aluminosilicate glass, silica glass, and low-alkali borosilicate glass can be used.

### Light-Reflective Member

The light-reflective member is in contact with the element lateral surfaces of the light-emitting element and the lateral surfaces of the light-transmissive member. Further, the light-reflective member is in contact with the outer peripheral region of the second element surface of the light-emitting element or the outer peripheral region of the first surface of the light-transmissive member.

The light-reflective member contains a base material and a light-reflective substance. As the base material of the light-reflective member, a resin member can be used. For the resin member, a thermosetting resin such as a silicone resin, a modified silicone resin, an epoxy resin, and a phenolic resin or a thermoplastic resin such as a polycarbonate resin, an acrylic resin, a methylpentene resin, and a polynorbornene resin can be used. A silicone resin, which has good resistance to light and heat, is particularly suitable.

The light-reflective member can be formed by a method such as compression molding, transfer molding, injection molding, printing, and potting according to the form.

Alternatively, for example, the light-reflective member can be formed of an inorganic material including boron nitride or an alkali metal silicate salt. In this case, titanium oxide or zirconium oxide can further be contained.

The light-reflective member can include both a resin member and an inorganic material.

The light-reflective member preferably has a reflectance of 70% or more at a peak emission wavelength of light emitted from the light-emitting element, more preferably 80% or more, and still more preferably 90% or more.

### Electroconductive Member

The light-emitting device includes a pair of electroconductive members that function as external terminals. The electroconductive members can further include an electroconductive member that does not contribute to electric conduction. For example, the electroconductive member that does not contribute to electric conduction can function as a heat dissipation member.

For example, for the electroconductive members, a processed metal plate or a member further including plating on a surface of the metal plate as the base material can be used. Examples of the base material of the metal plate include metals selected from copper, aluminum, silver, gold, zinc, chromium, tungsten, cobalt, nickel, iron, magnesium, rhodium, ruthenium, and other metals and alloys of these metals. These metals can form a single layer or a multilayer structure (such as a clad material). A metal plate containing 90% or more of copper as the main component is preferable. A nonmetal such as silicon and phosphorus can also be contained as a trace element.

The maximum thickness of the base member is preferably, for example, about 100 μm or more and 800 μm or less, more preferably about 150 μm or more and 200 μm or less.

The plating disposed on the surface of the base member is preferably a material having a higher reflectance than the reflectance of the base member. Examples of the plating layer include nickel, silver, gold, platinum, palladium, aluminum, tungsten, molybdenum, ruthenium, and rhodium. Examples of the multilayer structure include Ni/Pd/Au, Ni/Pt/Au, and Ni/Au/Ag, and among them, Ni/Pd/Au is preferable. The thickness of the plating is preferably about 1 μm or more and 10 μm or less, more preferably 1.5 μm or more and 6 μm or less.

The electroconductive members can be wiring disposed on an insulating base member formed of ceramic, a glass epoxy resin, a BT resin, or the like, or a sputtered film or a thin film layer such as plating connected to the electrodes of the light-emitting element. For these metal layers, the same material as the material of the plating disposed on the surface of the plate-shaped electroconductive members described above can be used.

### Electroconductive Bonding Member

The electroconductive bonding members are members that are electroconductive and electrically connect the electrodes of the light-emitting element to the electroconductive members. For a material of the electroconductive bonding members, for example, solder, metal paste, bumps, or the like can be used. Examples of the solder include Au-Sn, Sn-Ag-Cu, Sn-Cu, Sn-Sb, Sn-Bi, Sn-In, Sn-Pb, and Ni-Sn. Examples of the metal paste include Ag paste and Cu paste. Examples of the bumps include stud bumps and plating bumps formed of Au or the like.

For example, embodiments of the present invention are as follows.

### Clause 1

A light-emitting device comprising:

a light-emitting element including

a semiconductor layered body having a first element surface, a second element surface opposite to the first element surface, and a plurality of element lateral surfaces between the first element surface and the second element surface, and

a pair of electrodes;

a light-transmissive member having a first surface facing the second element surface, a second surface opposite to the first surface, and a plurality of lateral surfaces between the first surface and the second surface;

a bonding member between the second element surface of the light-emitting element and the first surface of the light-transmissive member; and

a light-reflective member in contact with the element lateral surfaces of the light-emitting element, the lateral surfaces of the light-transmissive member, and a lateral surface of the bonding member, the light-reflective member being in contact with an outer peripheral region of the second element surface of the light-emitting element or an outer peripheral region of the first surface of the light-transmissive member in a top view.

### Clause 2

The light-emitting device according to clause 1, wherein the lateral surface of the bonding member includes an inclined surface in a cross-sectional view.

### Clause 3

The light-emitting device according to clause 1 or 2, wherein an upper end of the lateral surface of the bonding member in contact with the first surface of the light-transmissive member is located outward of a lower end of the lateral surface of the bonding member in contact with the second element surface of the light-emitting element in a cross-sectional view.

### Clause 4

The light-emitting device according to any one of clauses 1 to 3, wherein an area of the first surface of the light-transmissive member is equal to or slightly larger than an area of the light-emitting element in a top view.

### Clause 5

The light-emitting device according to any one of clauses 1 to 4, wherein the bonding member is a polysilazane cured product.

### Clause 6

The light-emitting device according to any one of clauses 1 to 5, wherein the light-transmissive member contains a wavelength conversion substance.

### Clause 7

A method of manufacturing a light-emitting device, comprising:

providing a light-emitting element including,

a semiconductor layered body having a first element surface, a second element surface opposite to the first element surface, and a plurality of element lateral surfaces between the first element surface and the second element surface, and

a pair of electrodes;

providing a light-transmissive member having a first surface facing the second element surface, a second surface opposite to the first surface, and a plurality of lateral surfaces between the first surface and the second surface;

disposing an unhardened bonding member on the second element surface or on the first surface of the light-transmissive member;

hardening the bonding member in a state in which the unhardened bonding member is caused to extend on at least a portion of the element lateral surfaces of the light-emitting element and at least a portion of the lateral surfaces of the light-transmissive member by pressing the unhardened bonding member disposed between the second element surface and the first surface of the light-transmissive member via the light-transmissive member or the light-emitting element;

at least partially removing the bonding member covering at least a portion of the element lateral surfaces of the light-emitting element and at least a portion of the lateral surfaces of the light-transmissive member to at least partially expose an outer peripheral region of the second element surface of the light-emitting element or an outer peripheral region of the first surface of the light-transmissive member; and

forming a light-reflective member in contact with the element lateral surfaces of the light-emitting element, the lateral surfaces of the light-transmissive member, a lateral surface of the bonding member, and the outer peripheral region of the second element surface of the light-emitting element or the outer peripheral region of the first surface of the light-transmissive member.

### Clause 8

The method of manufacturing a light-emitting device according to clause 7, wherein the at least partial removing of the bonding member is performed by discharging a dry ice particle onto the bonding member.

### Clause 9

The method of manufacturing a light-emitting device according to clause 8, wherein the at least partial removing of the bonding member includes discharging the dry ice particle with an exit of a nozzle configured to discharge the dry ice particle being inclined with respect to the element lateral surfaces of the light-emitting element or the lateral surfaces of the light-transmissive member such that the nozzle scans in a thickness direction of the bonding member.

### Clause 10

The method of manufacturing a light-emitting device according to any one of clauses 7 to 9, wherein the at least partial removing of the bonding member includes forming at least a portion of the lateral surface of the bonding member into a shape depressed from the element lateral surfaces of the light-emitting element or the lateral surfaces of the light-transmissive member in a cross-sectional view.

### Clause 11

The method of manufacturing a light-emitting device according to any one of clauses 7 to 10, wherein the at least partial removing of the bonding member includes forming the lateral surface of the bonding member into an inclined surface in a cross-sectional view.

What is claimed is:

1. A light-emitting device comprising:
a light-emitting element including
a semiconductor layered body having a first element surface, a second element surface opposite to the first element surface, and a plurality of element lateral surfaces between the first element surface and the second element surface, and
a pair of electrodes;
a light-transmissive member having a first surface facing the second element surface, a second surface opposite to the first surface, and a plurality of lateral surfaces between the first surface and the second surface;
a bonding member between the second element surface of the light-emitting element and the first surface of the light-transmissive member; and
a light-reflective member in contact with the element lateral surfaces of the light-emitting element, the lateral surfaces of the light-transmissive member, and a lateral surface of the bonding member, the light-reflective member being in contact with an outer peripheral region of the second element surface of the light-emitting element or an outer peripheral region of the first surface of the light-transmissive member.

2. The light-emitting device according to claim 1, wherein the lateral surface of the bonding member includes an inclined surface in a cross-sectional view.

3. The light-emitting device according to claim 1, wherein an upper end of the lateral surface of the bonding member in contact with the first surface of the light-transmissive member is located outward of a lower end of the lateral surface of the bonding member in contact with the second element surface of the light-emitting element in a cross-sectional view.

4. The light-emitting device according to claim 2, wherein an upper end of the lateral surface of the bonding member in contact with the first surface of the light-transmissive member is located outward of a lower end of the lateral surface of the bonding member in contact with the second element surface of the light-emitting element in a cross-sectional view.

5. The light-emitting device according to claim 1, wherein an area of the first surface of the light-transmissive member is equal to or slightly larger than an area of the light-emitting element in a top view.

6. The light-emitting device according to claim 2, wherein an area of the first surface of the light-transmissive member is equal to or slightly larger than an area of the light-emitting element in a top view.

7. The light-emitting device according to claim 3, wherein an area of the first surface of the light-transmissive member is equal to or slightly larger than an area of the light-emitting element in a top view.

8. The light-emitting device according to claim 4, wherein an area of the first surface of the light-transmissive member is equal to or slightly larger than an area of the light-emitting element in a top view.

9. The light-emitting device according to claim 1, wherein the bonding member is a polysilazane cured product.

10. The light-emitting device according to claim 1, wherein the light-transmissive member contains a wavelength conversion substance.

11. A method of manufacturing a light-emitting device, the method comprising:
providing a light-emitting element including
a semiconductor layered body having a first element surface, a second element surface opposite to the first element surface, and a plurality of element lateral surfaces between the first element surface and the second element surface, and
a pair of electrodes;
providing a light-transmissive member having a first surface facing the second element surface, a second surface opposite to the first surface, and a plurality of lateral surfaces between the first surface and the second surface;
disposing an unhardened bonding member on the second element surface or on the first surface of the light-transmissive member;
hardening the bonding member in a state in which the unhardened bonding member is caused to extend on at least a portion of the element lateral surfaces of the light-emitting element and at least a portion of the lateral surfaces of the light-transmissive member by pressing the unhardened bonding member disposed between the second element surface and the first surface of the light-transmissive member via the light-transmissive member or the light-emitting element;
at least partially removing the bonding member covering at least a portion of the element lateral surfaces of the light-emitting element and at least a portion of the lateral surfaces of the light-transmissive member to at least partially expose an outer peripheral region of the second element surface of the light-emitting element or an outer peripheral region of the first surface of the light-transmissive member; and
forming a light-reflective member in contact with
the element lateral surfaces of the light-emitting element,
the lateral surfaces of the light-transmissive member,
a lateral surface of the bonding member, and
the outer peripheral region of the second element surface of the light-emitting element or the outer peripheral region of the first surface of the light-transmissive member.

12. The method of manufacturing a light-emitting device according to claim 11, wherein the at least partially removing of the bonding member is performed by discharging a dry ice particle onto the bonding member.

13. The method of manufacturing a light-emitting device according to claim 12, wherein the at least partially removing of the bonding member includes discharging the dry ice particle with an exit of a nozzle configured to discharge the dry ice particle being inclined with respect to the element lateral surfaces of the light-emitting element or the lateral surfaces of the light-transmissive member such that the nozzle scans in a thickness direction of the bonding member.

14. The method of manufacturing a light-emitting device according to claim 11, wherein the at least partially removing of the bonding member includes forming at least a portion of the lateral surface of the bonding member into a shape depressed from the element lateral surfaces of the light-emitting element or the lateral surfaces of the light-transmissive member in a cross-sectional view.

15. The method of manufacturing a light-emitting device according to claim 12, wherein the at least partially removing of the bonding member includes forming at least a portion of the lateral surface of the bonding member into a shape depressed from the element lateral surfaces of the light-emitting element or the lateral surfaces of the light-transmissive member in a cross-sectional view.

16. The method of manufacturing a light-emitting device according to claim 13, wherein the at least partially removing of the bonding member includes forming at least a portion of the lateral surface of the bonding member into a shape depressed from the element lateral surfaces of the light-emitting element or the lateral surfaces of the light-transmissive member in a cross-sectional view.

17. The method of manufacturing a light-emitting device according to claim 11, wherein the at least partially removing of the bonding member includes forming the lateral surface of the bonding member into an inclined surface in a cross-sectional view.

18. The method of manufacturing a light-emitting device according to claim 12, wherein the at least partially removing of the bonding member includes forming the lateral surface of the bonding member into an inclined surface in a cross-sectional view.

19. The method of manufacturing a light-emitting device according to claim 13, wherein the at least partially removing of the bonding member includes forming the lateral surface of the bonding member into an inclined surface in a cross-sectional view.

20. The method of manufacturing a light-emitting device according to claim 14, wherein the at least partially removing of the bonding member includes forming the lateral surface of the bonding member into an inclined surface in a cross-sectional view.
